(19) United States
(12) Patent Application Publication
(10) Pub. No.: US 2025/0334514 A1
(43) Pub. Date: Oct. 30, 2025

(54) EUV MASK INSPECTION APPARATUS AND METHOD THROUGH ILLUMINATION CONTROL

(71) Applicant: IUCF-HYU (INDUSTRY-UNIVERSITY COOPERATION FOUNDATION HANYANG UNIVERSITY), Seoul (KR)

(72) Inventors: Jinho AHN, Seoul (KR); Seungchan MOON, Seoul (KR); Young Woong KIM, Seoul (KR); Dong Gi LEE, Seoul (KR); Jin Hyuk CHOI, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/870,099

(22) PCT Filed: May 25, 2023
(86) PCT No.: PCT/KR2023/007158

§ 371 Date: Nov. 27, 2024

(30) Foreign Application Priority Data
Jun. 2, 2022 (KR) 10-2022-0067753

(51) Int. Cl. G01N 21/47; G01N 21/95

(52) U.S. Cl. CPC G01N 21/4788; G01N 21/95; G01N 2201/0636; G01N 2201/105

(57) ABSTRACT

An EUV mask inspection apparatus is provided. The EUV mask inspection apparatus comprises: a light source for generating EUV light; a mirror for changing a path of light such that the EUV light generated from the light source is emitted to a mask; a mirror stage coupled to the mirror and controlling the position of the mirror such that an incident angle at which the EUV light is emitted to the mask is controlled; and a detection array for collecting the EUV light diffracted through the mask to obtain a diffraction pattern of the diffracted EUV light, wherein an illumination system is implemented by combining diffraction patterns of first EUV light and second EUV light emitted at different angles to the same region of the mask.

### TECHNICAL FIELD

The present invention relates to an EUV mask inspection apparatus and a method through illumination control, and more particularly, to an apparatus and a method for inspecting an EUV mask to implement an optimized illumination system according to the mask pattern.

### BACKGROUND ART

When defects or contaminations of a mask are found during an EUV exposure process, a process of correcting the pattern defects or cleaning the contaminants rather than manufacturing a mask again to apply the repaired mask to mass production processes may lower semiconductor manufacturing costs. Even when the mask undergoes the correcting and cleaning process, a success of the correcting may be confirmed by directly exposing a wafer with an exposure machine and then reviewing the exposed wafer with an SEM. However, because it takes a lot of money and time for verification, it is necessary to verify in advance the impact of mask defects on wafers through a measurement on an EUV mask space image using a microscope capable of illustrating an optical system of an EUV exposure machine. In addition, since the EUV mask is manufactured in the form of 40 pairs of Mo/Si-based multilayer thin films to complement characteristics of EUV light of 13.5 nm, it is possible to evaluate the presence or absence of surface defects using deep ultraviolet (DUV) or E-beam. However, phase defects occurring within multilayer films may be accurately measured only through inspection using EUV light for accurate mask space image measurement, and this is called the actinic inspection technology.

In the related art, in order to evaluate the mask imaging characteristics transferred onto the wafer inside the exposure high-NA EUV mask inspection technology using an machine, objective lens having an NA of 0.55 while using EUV light has been studied to evaluate high-resolution mask imaging performance. However, the problems, as the high such manufacturing difficulty and price issues of the above lens, the decrease in focus depth according to increasing NA, and the technical limitation for ultra-precision alignment, may occur. Further, because defects present in the EUV mask may or may not be transferred to the wafer inside the exposure machine depending on the illumination system used, accurate mask imaging characteristics are possible only through the conditions of illumination system applied in the exposure machine.

In regard to the most relevant technologies related to illumination system control and mask imaging, there is a technology to transfer a mask onto a wafer by controlling the illumination system using a facet mirror in an exposure machine. The facet mirror is composed of a group of more than 100 separate mirrors and each mirror is independently adjustable to a fine angle so as to adjust an incidence angle of EUV light irradiated onto the EUV mask, and accordingly, the illumination system may be controlled.

However, because the facet mirror is exclusively made by Carl Zeiss company, there are no commercialized products, the design difficulty is very high, and production also costs astronomical amounts of money. Since the facet mirror is composed of hundreds of independent mirrors and significantly large in size, it is also very difficult to simultaneously and finely control the mirrors. Since the additional installation of optical systems for implementing the above optical system may cause a decrease in the amount of light due to the characteristics of EUV light, thereby exerting a negative impact on the evaluation of mask imaging performance, the additional installation is currently not being used for the mask imaging characteristic inspection technology.

### DISCLOSURE

### Technical Problem

One technical problem to be solved by the present invention is to provide an apparatus and a method for inspecting an EUV mask through illumination control.

Another technical problem to be solved by the present invention is to provide an apparatus and a method for inspecting an EUV mask to implement various illumination systems.

Still another technical problem to be solved by the present invention is to provide an apparatus and a method for inspecting an EUV mask without using expensive facet mirrors.

Still another technical problem to be solved by the present invention is to provide an apparatus and a method for inspecting an EUV mask to obtain high-resolution spatial domain images regardless of a pattern type of the mask.

Still another technical problem to be solved by the present invention is to provide an apparatus and a method for inspecting an EUV mask to irradiate the same region of the mask with EUV light at various angles.

Still another technical problem to be solved by the present invention is to provide an apparatus and a method for inspecting an EUV mask to improve mask inspection accuracy.

The technical problems to be solved by the present invention are not limited to the above description. One technical problem to be solved by the present invention is to provide an apparatus and a method for inspecting an EUV mask through illumination control.

Another technical problem to be solved by the present invention is to provide an apparatus and a method for inspecting an EUV mask to implement various illumination systems.

Still another technical problem to be solved by the present invention is to provide an apparatus and a method for inspecting an EUV mask without using expensive facet mirrors.

Still another technical problem to be solved by the present invention is to provide an apparatus and a method for inspecting an EUV mask to obtain high-resolution spatial domain images regardless of a pattern type of the mask.

Still another technical problem to be solved by the present invention is to provide an apparatus and a method for inspecting an EUV mask to irradiate the same region of the mask with EUV light at various angles.

Still another technical problem to be solved by the present invention is to provide an apparatus and a method for inspecting an EUV mask to improve mask inspection accuracy.

The technical problems to be solved by the present invention are not limited to the above description.

### Technical Solution

In order to solve the above-mentioned technical problems, The present invention provides an EUV mask inspection apparatus.

According to one embodiment, the EUV mask inspection apparatus includes: a light source for generating EUV light; a mirror for changing a path of light such that the EUV light generated from the light source is emitted to a mask; a mirror stage coupled to the mirror to control a position of the mirror such that an incident angle of the EUV light emitted to the mask is controlled; and a detection array for collecting the EUV light in diffracted through the mask to obtain a diffraction pattern of the diffracted EUV light, wherein an illumination system is implemented by combining diffraction patterns of first EUV light and second EUV light emitted at different angles to a same region of the mask.

According to one embodiment, the detection array may implement the illumination system by obtaining a target diffraction pattern by synthesizing a first diffraction pattern for the first EUV light and a second diffraction pattern for the second EUV light, and obtain an aerial image of a region of the mask irradiated with the first EUV light and the second EUV light through the target diffraction pattern.

According to one embodiment, the illumination system implemented by synthesizing the diffraction patterns for the first EUV light and the second EUV light may include a dipole illumination system having two poles spaced apart from each other at an angle of 180°.

According to one embodiment, the first EUV light may be irradiated to a first region of the mask with a large angle pole (LAP) at an angle greater than 6° of an incidence angle with respect to a normal on an upper surface of the mask, and the second EUV light may be irradiated to the first region of the mask with a small angle pole (SAP) at an angle smaller than 6° of the incidence angle with respect to the normal on the upper surface of the mask.

According to one embodiment, the EUV mask inspection apparatus further includes a pinhole arranged on the mask, wherein the pinhole guides the EUV light irradiated to the mask to be focused on a specific region of the mask.

According to one embodiment, the pinhole may include an incident hole for guiding the EUV light to be irradiated from the mirror to the mask, and a diffraction hole for guiding the EUV light diffracted from the mask to be collected by the detection array.

According to one embodiment, the incident hole may include first to fourth incident holes, in which the second incident hole has a diameter larger than a diameter of the first incident hole, the third incident hole has a diameter larger than the diameter of the second incident hole, and the fourth incident hole has a diameter larger than the diameter of the third incident hole. According to one embodiment, the illumination system implemented by synthesizing the diffraction patterns for the first EUV light and the second EUV light may be implemented using one among a V-dipole illumination system having two poles spaced apart from each other at an angle of 180° in a vertical direction, an H-dipole illumination system having two poles spaced apart from each other at an angle of 180° in a horizontal direction, a quadrupole illumination system having four poles spaced apart from each other at an angle of 90°, a circular illumination system having a circular pole, and an annular illumination system having an annular pole.

In order to solve the above-mentioned technical problems, the present invention provides an EUV mask inspection method.

According to one embodiment, the EUV mask inspection method includes: generating first EUV light from a light source; irradiating the first EUV light onto a first region of the mask at a first angle by changing a path of the first EUV light through a mirror; collecting the first EUV light diffracted from the first region of the mask to obtain a first diffraction pattern of the diffracted first EUV light; generating second EUV light from the light source; irradiating the second EUV light onto the first region of the mask at a second angle different from the first angle by changing a path of the second EUV light through the mirror; collecting the second EUV light diffracted from the first region of the mask to obtain a second diffraction pattern of the diffracted second EUV light; and implementing an illumination system by synthesizing the first diffraction pattern and the second diffraction pattern.

According to one embodiment, the irradiating of the first EUV light onto the first region of the mask at the first angle may include: changing the path of the first EUV light by changing a position of the mirror so that the first EUV light generated from the light source is irradiated to the mask; and controlling the position of a pinhole arranged in the mask to guide the first EUV light having the path changed through the mirror to be irradiated to the first region of the mask, and wherein the irradiating of the second EUV light onto the first region of the mask at the second angle may include: changing the path of the second EUV light by changing the position of the mirror so that the second EUV light generated from the light source is irradiated to the mask; and controlling the position of the pinhole arranged in the mask to guide the second EUV light having the path changed through the mirror to be irradiated to the second region of the mask.

According to one embodiment, the EUV mask inspection method further includes: after the implementing of the illumination system by synthesizing the first diffraction pattern and the second diffraction pattern, repeatedly calculating a target diffraction pattern synthesized from the first diffraction pattern and the second diffraction pattern by using a phase recovery algorithm, thereby obtaining an aerial image for the first region of the mask.

In order to solve the above-mentioned technical problems, the present invention provides a mirror tilting apparatus.

According to one embodiment, the mirror tilting apparatus includes: an upper mirror stage mounted thereon with a mirror for reflecting EUV light to change a path of the EUV light; and a lower mirror stage coupled to the upper mirror stage to support the upper mirror stage, wherein the lower mirror stage performs linear reciprocating motions in a first direction and in a second direction perpendicular to the first direction, respectively, and the upper mirror stage rotates clockwise or counterclockwise about a third direction perpendicular to the first and second directions and the second direction as axes.

According to one embodiment, the upper mirror stage may include a first upper drive module having an ‘L’ shape and rotating clockwise or counterclockwise about the third direction as an axis; a second upper drive module having an ‘L’ shape and coupled into the first upper drive module to rotate clockwise or counterclockwise about the second direction as an axis; and a mirror mounting module disposed inside the second upper drive module and having a space mounted therein with the mirror.

According to one embodiment, the lower mirror stage may include: a first lower drive module linearly reciprocating along the second direction; and a second lower drive module disposed on the first lower drive module and linearly reciprocating along the first direction.

### Advantageous Effects

The EUV mask inspection apparatus according to the embodiments of the present invention may implement various illumination systems, thereby obtaining high-resolution spatial domain images regardless of a pattern type of the EUV mask, so that the accuracy of EUV mask inspection can be improved.

In addition, various illumination systems may be implemented without using expensive facet mirrors, so that economic costs for the EUV mask inspection can be significantly reduced.

### DESCRIPTION OF DRAWINGS

FIG. 1 is a view for explaining an EUV mask inspection apparatus according to one embodiment of the present invention.

FIGS. 2 and 3 are views for explaining pinholes of the EUV mask inspection apparatus according to one embodiment of the present invention.

FIG. 4 is a view for explaining the implementation of a conventional illumination system through the EUV mask inspection apparatus according to one embodiment of the present invention.

FIG. 5 is a view for explaining LAP irradiation through the EUV mask inspection apparatus according to one embodiment of the present invention.

FIG. 6 is a view for explaining SAP irradiation through the EUV mask inspection apparatus according to one embodiment of the present invention.

FIGS. 7 and 8 are views for explaining the implementation of a dipole illumination system through the EUV mask inspection apparatus according to one embodiment of the present invention.

FIG. 9 is a view for explaining an example of an illumination system that can be implemented through the EUV mask inspection apparatus according to one embodiment of the present invention.

FIG. 10 is a view for explaining another example of the illumination system that can be implemented through the EUV mask inspection apparatus according to one embodiment of the present invention.

FIG. 11 is a view for explaining a process of obtaining a spatial domain image through a detection array of the EUV mask inspection apparatus according to one embodiment of the present invention.

FIG. 12 shows photographs comparing a spatial domain image through a conventional illumination system with a spatial domain image through a dipole illumination system with respect to the same mask pattern.

FIG. 13 is a view comparing intensity distribution of a spatial domain image through a conventional illumination system with intensity distribution of a spatial domain image through a dipole illumination system with respect to the same mask pattern.

FIG. 14 is a view for explaining a mirror stage of the EUV mask inspection apparatus according to one embodiment of the present invention.

FIG. 15 is a view for explaining an upper mirror stage of the mirror stage according to one embodiment of the present invention.

FIGS. 16 and 17 are drawings for explaining the driving of the upper mirror stage according to one embodiment of the present invention.

FIG. 18 is a view for explaining the lower mirror stage of the mirror stage according to one embodiment of the present invention.

FIGS. 19 and 20 are drawings for explaining the driving of the lower mirror stage according to one embodiment of the present invention.

### BEST MODE

### Mode for Invention

Hereinafter, exemplary embodiments of the present invention will be described in detail with reference to the accompanying drawings. However, the technical idea of the present invention is not limited to the exemplary embodiments described herein and may be embodied in other forms. Further, the embodiments are provided to enable contents disclosed herein to be thorough and complete and provided to enable those skilled in the art to fully understand the idea of the present invention.

In this specification, when one component is mentioned as being on another component, it signifies that the one component may be placed directly on another component or a third component may be interposed therebetween. In addition, in the drawings, thicknesses of layers and regions may be exaggerated to effectively describe the technology of the present invention.

In addition, although terms such as first, second and third are used to describe various components in various embodiments of the present specification, the components will not be limited by the terms. The above terms are used merely to distinguish one component from another. Accordingly, a first component referred to in one embodiment may be referred to as a second component in another embodiment. Each embodiment described and illustrated herein may also include a complementary embodiment. In addition, the term “and/or” is used herein to include at least one of the components listed before and after the term.

The singular expression herein includes a plural expression unless the context clearly specifies otherwise. In addition, it will be understood that the term such as “include” or “have” herein is intended to designate the presence of feature, number, in the step, component, or a combination thereof recited i specification, and does not preclude the possibility of the presence or addition of one or more other features, numbers, steps, components, or combinations thereof. In addition, the term “connection” is used herein to include both indirectly connecting a plurality of components and directly connecting the components.

In addition, in the following description of the embodiments of the present invention, the detailed description of known functions and configurations incorporated herein will be omitted when it possibly makes the subject matter of the present invention unclear unnecessarily.

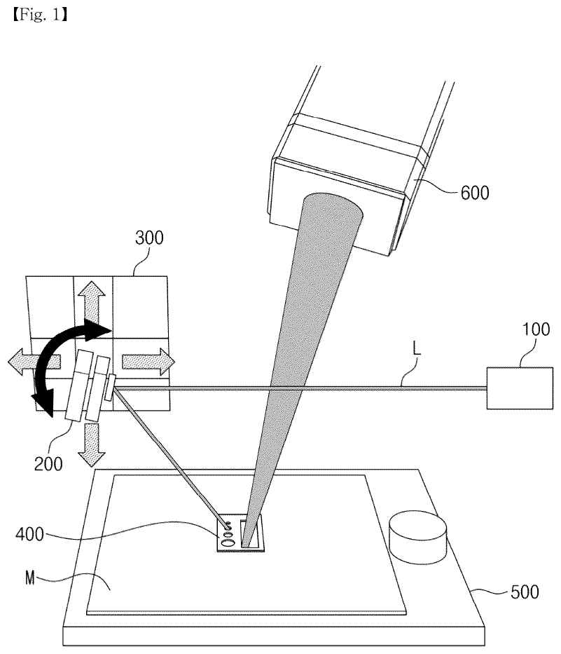

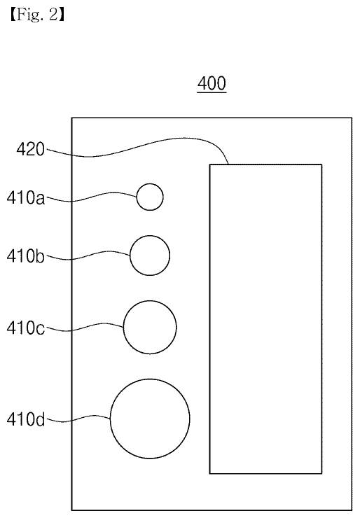

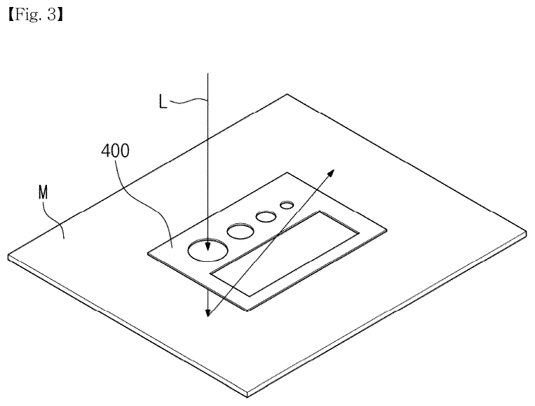

FIG. 1 is a view for explaining an EUV mask inspection apparatus according to one embodiment of the present invention. FIGS. 2 and 3 are views for explaining pinholes of the EUV mask inspection apparatus according to one embodiment of the present invention.

Referring to FIGS. 1 to 3, the EUV mask inspection apparatus according to the embodiments of the present invention may include a light source 100, a mirror 200, a mirror stage 300, a pinhole 400, a pinhole stage (not shown), a mask stage 500, and a detection array 600. Hereinafter, each component will be described.

The light source 100 may generate coherent extreme ultra violet (EUV) light having a wavelength of 13.5 nm. The EUV light L generated from the light source 100 may be provided to the mirror 200.

The mirror 200 may change a path of the EUV light L by reflecting the EUV light L. The EUV light L having path changed through the mirror 200 may be provided to a mask M. For example, the mirror 200 may be a toroidal multilayer thin film mirror.

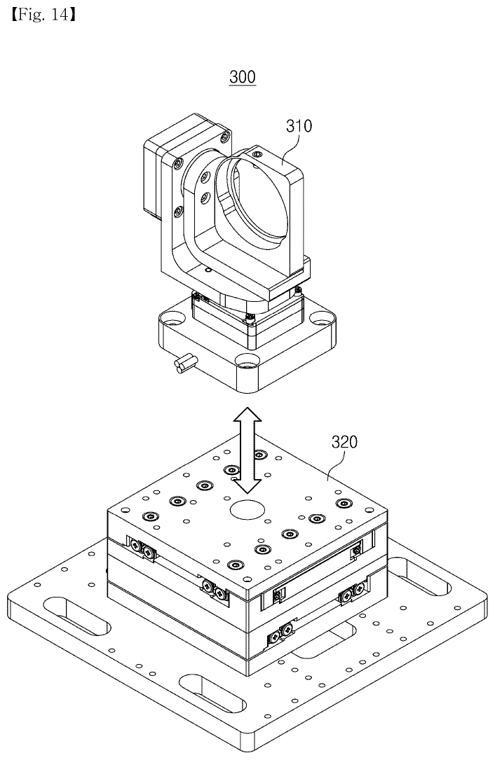

The mirror stage 300 may be coupled with the mirror 200. The mirror stage 300 may control a position of the mirror 200 to control an incident angle of the EUV light L irradiated to the mask M. In other words, when the mirror stage 300 is controlled, the angle of the EUV light L irradiated to the mask M may be variously controlled. The mirror stage 300 will be described later in more detail with reference to FIGS. 14 to 20.

The pinhole 400 may be arranged in the mask M. The pinhole 400 may guide the EUV light L irradiated to the mask M to be focused on a specific region of the mask M. In other words, the positional accuracy of the EUV light L focused on the mask M may be improved by the pinhole 400.

According to one embodiment, the pinhole 400 may include first to fourth incident holes 410a, 410b, 410c and 410d and a diffraction hole 420. The first to fourth incident holes 410a, 410b, 410c and 410d may be defined as holes for guiding the EUV light L to be irradiated from the mirror 200 to the mask M. In contrast, the diffraction hole 420 may be defined as a hole for guiding the EUV light L diffracted from the mask M to be collected to the detection array 600. In other words, the EUV light L reflected through the mirror 200 may enter the mask M through one of the first to fourth incident holes 410a, 410b, 410c and 410d and then be diffracted from the mask M, and the EUV light L diffracted from the mask M may be provided to the detection array 600 through the diffraction hole 420.

According to one embodiment, the first to fourth incident holes 410a, 410b, 410c and 410d may have diameters different from each other. For example, the second incident hole 410b may have the diameter larger than the diameter of the first incident hole 410a, the third incident hole 410c may have the diameter larger than the diameter of the second incident hole 410b, and the fourth incident hole 410d may have the diameter larger than the diameter of the third incident hole 410c. Specifically, the diameter of the first incident hole 410a may be 10 μm. In contrast, the diameter of the second incident hole 410b may be 15 μm. In contrast, the diameter of the third incident hole 410c may be 20 μm. In contrast, the diameter of the fourth incident hole 410d may be 30 μm.

The pinhole stage (not shown) may control the position of the pinhole 400. According to one embodiment, the pinhole stage (not shown) may control the position of the pinhole 400 to allow the EUV light L to be irradiated to the mask M through the fourth incident hole 410d, and then may control the position of the pinhole 400 to allow the EUV light to be irradiated to the mask M sequentially through the third incident hole 410c, the second incident hole 410b and the first incident hole 410a. In other words, after the EUV light L is controlled to be irradiated to the mask M through the incident hole having the largest diameter, the EUV light L may be controlled to be irradiated to the mask M through the incident holes having gradually smaller diameters. Accordingly, the positional accuracy of the EUV light L focused on the mask M may be improved.

In other words, in the EUV mask inspection apparatus according to the embodiments of the present invention, the EUV light L may be controlled to be irradiated at different angles to the same region of the mask M by using the mirror 200, the mirror stage 300, the pinhole 400 and the pinhole stage (not shown).

The mask stage 500 may control the position of the mask M. According to one embodiment, the region of the mask M to be inspected may be changed through the mask stage 500.

According to one embodiment, the EUV mask inspection apparatus may further include a control unit (not shown). The control unit may calculate the inclination and position information of the mirror 200 by reversely calculating the angle of the EUV light L incident onto the mask M.

The detection array 600 may collect the EUV light L reflected and diffracted through the mask M to obtain a diffraction pattern of the reflected and diffracted EUV light L. In addition, the detection array 600 may obtain a spatial domain image (aerial image) of the mask M irradiated with the EUV light L by utilizing a coherent diffraction imaging (CDI) technique, which reconstructs an image by repeatedly calculating the diffraction pattern of the EUV light L through a phase recovery algorithm. The EUV mask inspection apparatus may check the aerial image to check defects, contaminations and the like of the mask M.

As described above, when the defects, contaminations and the like of the mask M are checked through the spatial domain image of the mask M, the accuracy may vary depending on the resolution of the spatial domain image. In other words, while the accuracy of inspection may be decreased by a low-resolution spatial domain image, the accuracy of inspection may be improved by a high-resolution spatial domain image.

The resolution of the spatial domain image may vary depending on an illumination system of the mask inspection apparatus. Particularly, different optimal illumination systems, which may achieve high resolution, depend on pattern types of the mask M. For example, a horizontal dense line (H-dense line) pattern may obtain high-resolution spatial domain images through a V-dipole illumination system, a vertical dense line (V-dense line) pattern may obtain high-resolution spatial domain images through an H-dipole illumination system, and a contact hole (C/H) pattern may obtain high-resolution spatial domain images through a quadrupole illumination system.

Because the conventional mask inspection apparatus implements the only one illumination system, it is difficult to obtain high-resolution spatial domain images for various masks. However, the EUV mask inspection apparatus according to the embodiments of the present invention can implement various illumination systems, so that high-resolution spatial domain images can be obtained regardless of pattern types of the mask. Hereinafter, the process of implementing various illumination systems using the EUV mask inspection apparatus according to the embodiments of the present invention will be described.

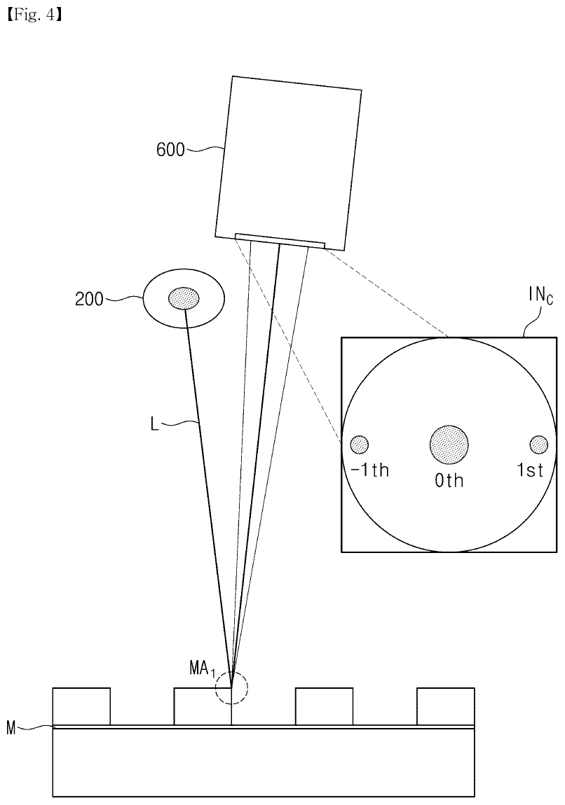

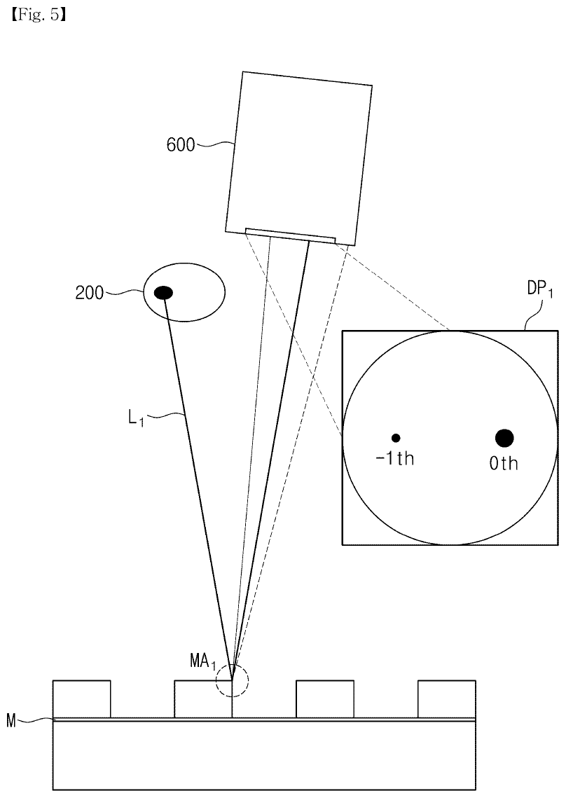

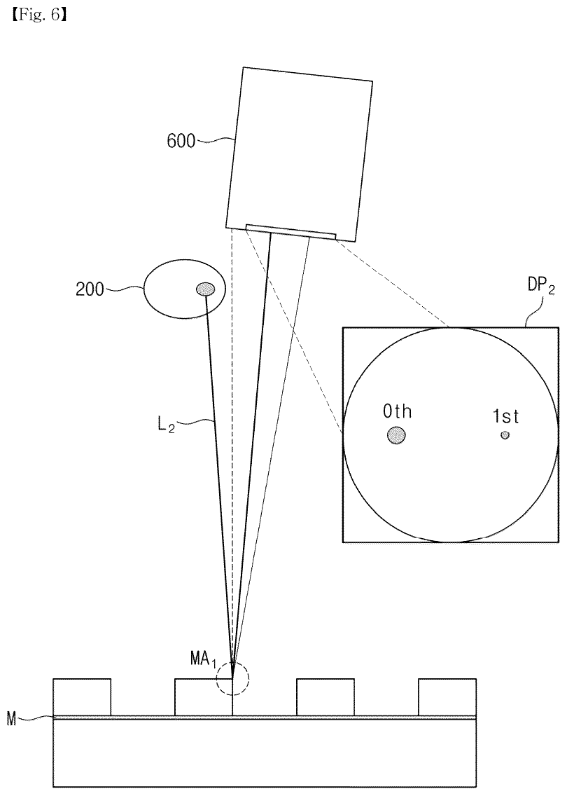

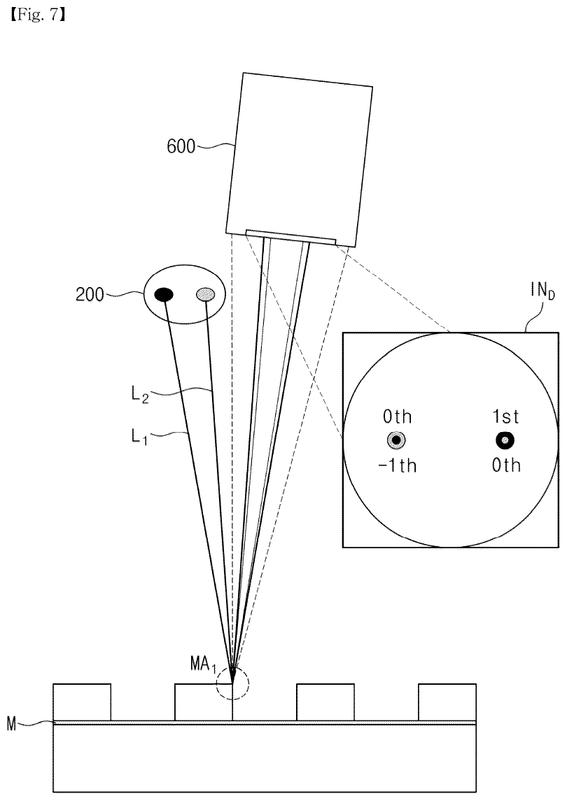

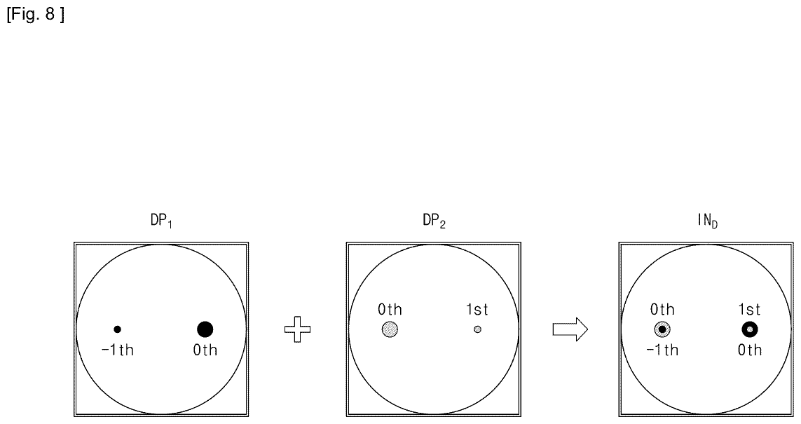

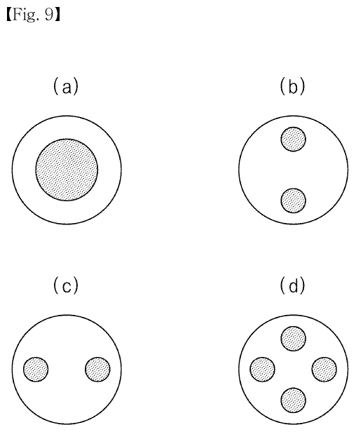

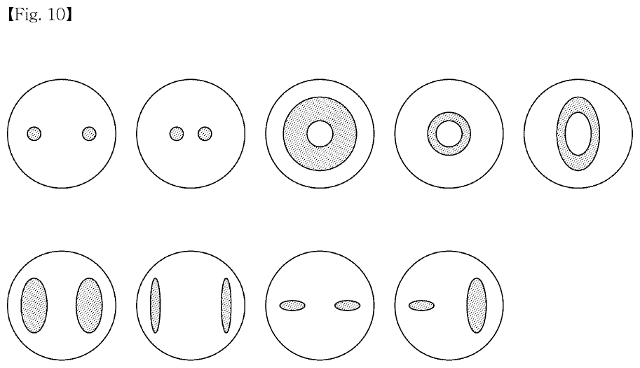

FIG. 4 is a view for explaining the implementation of the conventional illumination system through the EUV mask inspection apparatus according to one embodiment of the present invention; FIG. 5 is a view for explaining LAP irradiation through the EUV mask inspection apparatus according to one embodiment of the present invention; FIG. 6 is a view for explaining SAP irradiation through the EUV mask inspection apparatus according to one embodiment of the present invention; FIGS. 7 and 8 are views for explaining the implementation of a dipole illumination system through the EUV mask inspection apparatus according to one embodiment of the present invention; FIG. 9 is a view for explaining an example of an illumination system that can be implemented through the EUV mask inspection apparatus according to one embodiment of the present invention; and FIG. 10 is a view for explaining another example of the illumination system that can be implemented through the EUV mask inspection apparatus according to one embodiment of the present invention.

Referring to FIG. 4, the EUV light L reflected through the mirror 200 may be diffracted in a first region MA1 of the mask M and then collected to the detection array 600. The detection array 600 may obtain a diffraction pattern INC of the EUV light L. For example, the diffraction pattern INC of the EUV light L obtained through the detection array 600 may include 0th diffraction light 0th, first diffraction light 1st, and—first diffraction light—1th. The diffraction pattern of the EUV light L including the 0th diffraction light 0th, the first diffraction light 1st, and the—first diffraction light—1th may be the same as the diffraction pattern of the conventional illumination system. In other words, the EUV mask inspection apparatus may control the incident angle of the EUV light L irradiated onto the mask M to include the 0th diffraction light 0th, the first diffraction light 1st, and the —first diffraction light—1th in the diffraction pattern obtained through the detection array 600, so that the conventional illumination system can be implemented. The control of the incident angle of the EUV light L irradiated onto the mask M may be accomplished through the mirror stage 300.

Referring to FIG. 5, first EUV light L1 generated through the light source 100 may be reflected from the mirror 200 and then irradiated onto the mask M at a first angle. According to one embodiment, the first EUV light L1 may be irradiated to the first region MA1 of the mask M with a large angle pole (LAP) at an angle greater than 6° of an incidence angle with respect to a normal on an upper surface of the mask. According to one embodiment, the first EUV light L1 may be defined as EUV light irradiated to the mask M with LAP.

The first EUV light L1 reflected and diffracted from the first region MA1 of the mask M may be collected by the detection array 600, and the detection array 600 may obtain a diffraction pattern of the first EUV light L1. The diffraction pattern of the first EUV light L1 may be defined as a first diffraction pattern DP1.

As shown in FIG. 5, the first diffraction pattern DP1 may include 0th diffraction light 0th and—first diffraction light—1th. In other words, the EUV mask inspection apparatus may control the incident angle of the first EUV light L1 irradiated onto the mask M to include the 0th diffraction light 0th and the—first diffraction light—1th in the diffraction pattern obtained through the detection array 600. The control of the incident angle of the first EUV light L1 irradiated onto the mask M may be accomplished through the mirror stage 300.

Referring to FIG. 6, second EUV light L2 generated through the light source 100 may be reflected from the mirror 200 and then irradiated onto the mask M at a second angle different from the first angle. According to one embodiment, the second EUV light L2 may be irradiated to the first region MA1 of the mask M with a small angle pole (SAP) at an angle smaller than 6° of the incidence angle with respect to the normal on the upper surface of the mask. According to one embodiment, the second EUV light L2 may be defined as EUV light irradiated to the mask M with SAP. The second EUV light L2 reflected and diffracted from the first region MA1 of the mask M may be collected by the detection array 600, and the detection array 600 may obtain a diffraction pattern of the second EUV light L2. The diffraction pattern of the second EUV light L2 may be defined as a second diffraction pattern DP2.

As shown in FIG. 6, the second diffraction pattern DP2 may include 0th diffraction light 0th and first diffraction light 1st. In other words, the EUV mask inspection apparatus may control the incident angle of the second EUV light L2 irradiated onto the mask M to include the 0th diffraction light 0th and the first diffraction light 1st in the diffraction pattern obtained through the detection array 600. The control of the incident angle of the second EUV light L2 irradiated onto the mask M may be accomplished through the mirror stage 300.

Referring to FIGS. 7 and 8, the detection array 600 may synthesize the first diffraction pattern DP1 and the second diffraction pattern DP2. A pattern synthesized from the first diffraction pattern DP1 and the second diffraction pattern DP2 may be defined as a target diffraction pattern IND. The target diffraction pattern IND may be the same as a diffraction pattern of a dipole illumination system. In other words, the EUV mask inspection apparatus may synthesize the first diffraction pattern DP1 obtained from the first EUV light L1 and the second diffraction pattern DP2 obtained from the second EUV light L2, so that a dipole illumination system having two poles spaced apart from each other at an angle of 180° may be implemented.

As a result, the EUV mask inspection apparatus may irradiate multiple EUV lights at different angles to the same region of the mask M, obtain a diffraction pattern from each EUV light, and synthesize the obtained diffraction patterns, so that various illumination systems can be implemented. The illumination system implemented through the EUV mask inspection apparatus are shown in FIGS. 9 and 10. For example, as shown in (a) to (d) of FIG. 9, a Conventional illumination system (a), a V-dipole illumination system (b), an H-dipole illumination system (c), a Quadrupole illumination system (d) and the like may be implemented. In contrast, as shown in FIG. 10, an Annular illumination system may also be implemented. Various illumination systems may be implemented in addition to the illumination systems shown in FIGS. 9 and 10, and the present invention is not limited to types of illumination systems that can be implemented.

Accordingly, the EUV mask inspection apparatus may implement various illumination systems in a simple manner of controlling the incidence angle of EUV light just by using a toroidal mirror commonly used in EUV processes, so that high-resolution spatial domain images can be obtained for various masks without expensive equipment such as conventionally used facet mirrors.

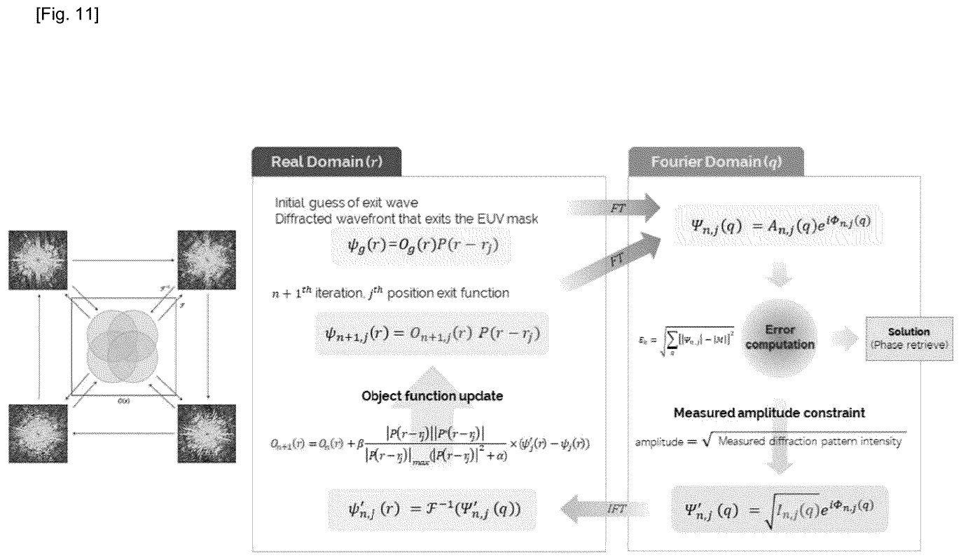

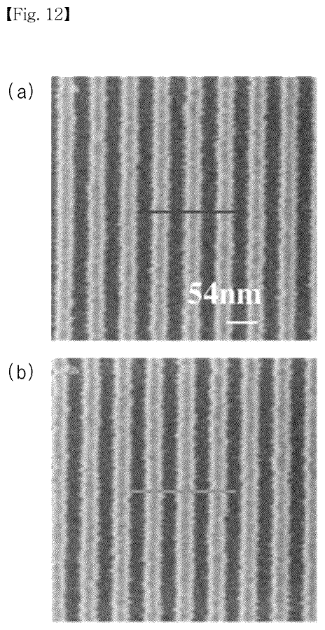

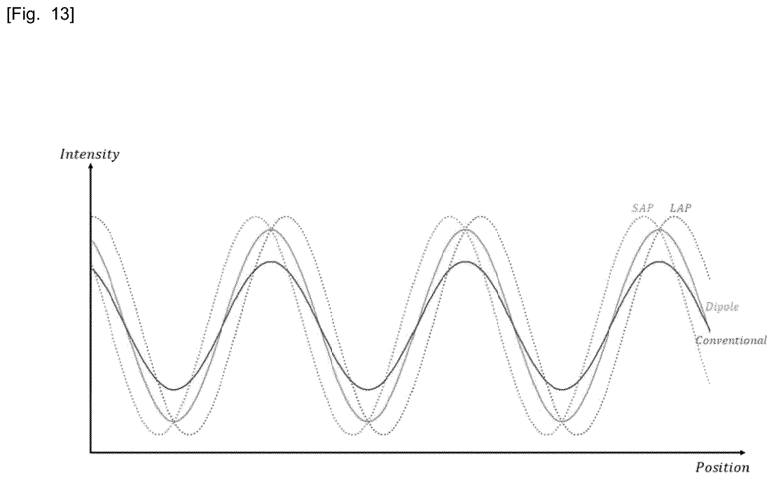

FIG. 11 is a view for explaining a process of obtaining a spatial domain image through a detection array of the EUV mask inspection apparatus according to one embodiment of the present invention; FIG. 12 shows photographs comparing a spatial domain image through a conventional illumination system with a spatial domain image through a dipole illumination system with respect to the same mask pattern; and FIG. 13 is a view comparing intensity distribution of a spatial domain image through a conventional illumination system with intensity distribution of a spatial domain image through a dipole illumination system with respect to the same mask pattern.

The detection array 600 may measure intensity of the EUV light L and then use the coherent diffraction imaging (CDI) technique to assign an arbitrary phase value to the measured intensity value and repeatedly calculate Fourier transform and Inverse Fourier transform, so that a phase of the image may be restored. For example, as shown in FIG. 11, a ptychography phase recovery algorithm may be used. Specifically, random values are assigned to a probe function P (r) and an object function O (r), an amplitude and a phase in a Fourier domain are calculated through the Fourier transform, the calculated amplitude is replaced by an amplitude value of the obtained diffraction pattern, and P (r) and O (r) obtained through the inverse Fourier transform are used to reduce an error between the calculated value and the measured value through an update function. The above-described process may be repeated until the error between the measured value and the calculated value becomes below a predetermined level. According to one embodiment, P (r) may be defined as EUV light irradiated onto the mask, and O (r) may be defined as a mask image.

Referring to FIG. 12, it compares a spatial domain image (a) obtained through the conventional illumination system with a spatial domain image (b) obtained through the dipole illumination system for a mask having a dense line pattern. In addition, referring to FIG. 13, it compares an intensity distribution (a) of the spatial domain image obtained through the conventional illumination system with an intensity distribution (b) of the spatial domain image obtained through the dipole illumination system for the mask having the dense line pattern.

As shown in FIGS. 12 and 13, in the case of masks having dense line patterns, it can be seen that contrast and resolution of an image are higher when the dipole illumination system is used than when the conventional illumination system is used.

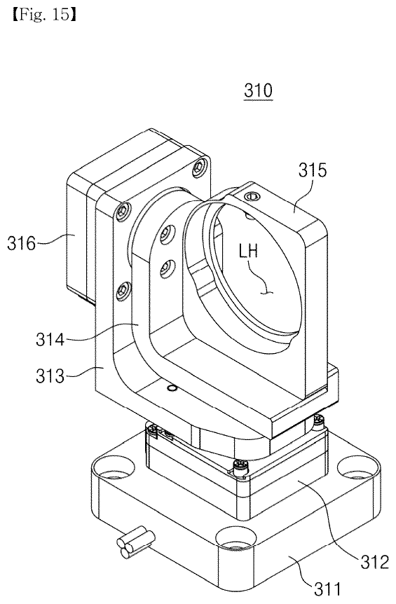

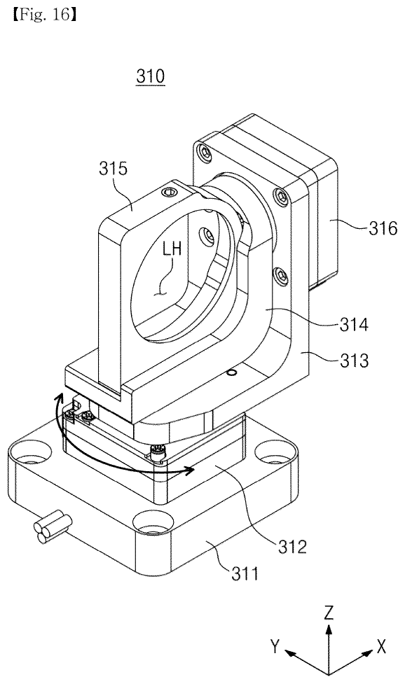

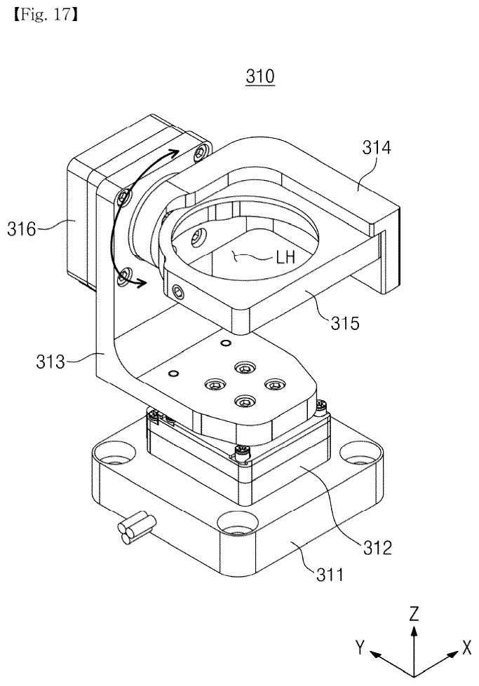

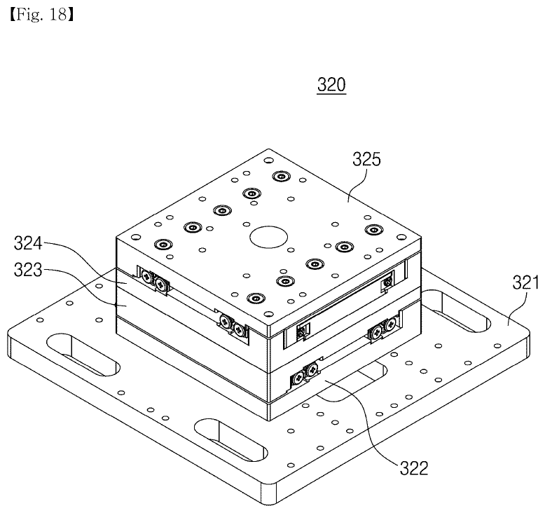

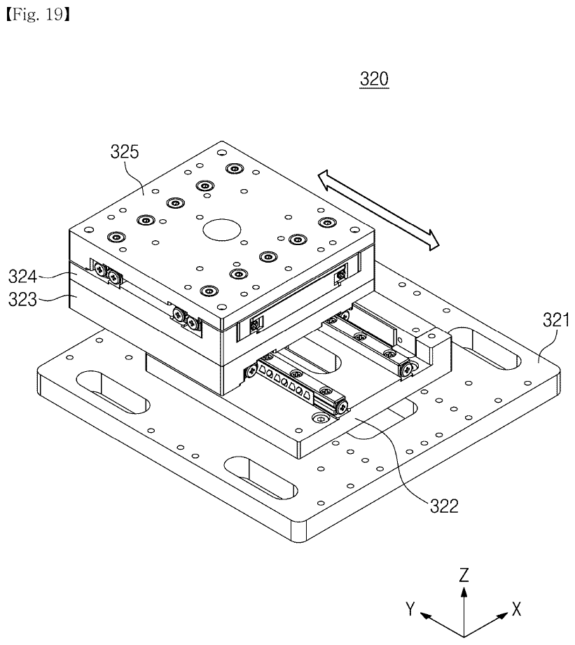

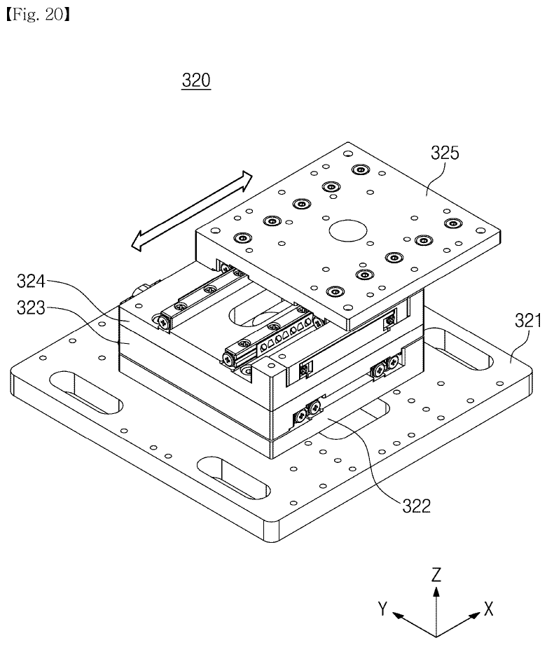

FIG. 14 is a view for explaining a mirror stage of the EUV mask inspection apparatus according to one embodiment of the present invention; FIG. 15 is a view for explaining an upper mirror stage of the mirror stage according to one embodiment of the present invention; FIGS. 16 and 17 are drawings for explaining the driving of the upper mirror stage according to one embodiment of the present invention; FIG. 18 is a view for explaining the lower mirror stage of the mirror stage according to one embodiment of the present invention; and FIGS. 19 and 20 are drawings for explaining the driving of the lower mirror stage according to one embodiment of the present invention.

Referring to FIG. 14, the mirror stage 300 may include: an upper mirror stage 310 mounted thereon with a mirror for reflecting EUV light to change a path of the EUV light; and a lower mirror stage 320 coupled to the upper mirror stage 310 to support the upper mirror stage. The mirror stage 300 may also be defined as a mirror tilting apparatus.

Referring to FIGS. 15 to 17, the upper mirror stage 310 may include a first upper plate 311, a second upper plate 312, a first upper drive module 313, a second upper drive module 314, a mirror mounting module 315, and a third upper plate 316.

The first upper plate 311 may have a rectangular plate shape composed of sides extending in a first direction and sides extending in a second direction perpendicular to the first direction. According to one embodiment, the first direction may be an X-axis direction shown in FIGS. 16 and 17. In contrast, the second direction may be a Y-axis direction shown in FIGS. 16 and 17.

The second upper plate 312 may be disposed on the first upper plate 311 and fixedly coupled to the first upper plate 311. According to one embodiment, the second upper plate 312 may also have a rectangular plate shape like the first upper plate 311, however, the area of the second upper plate 312 may be smaller than the area of the first upper plate 311.

The first upper drive module 313 may be disposed on the second upper plate 312. According to one embodiment, the first upper drive module 313 may have an ‘L’ shape. As shown in FIG. 16, the first upper drive module 313 may rotate clockwise or counterclockwise about a third direction, as an axis, which is a direction perpendicular to the first direction (X-axis direction) and the second direction (Y-axis direction). According to one embodiment, the third direction may be a Z-axis direction shown in FIGS. 16 and 17.

The second upper drive module 314 may be disposed into the first upper drive module 313. According to one embodiment, the second upper drive module 314 may also have an ‘L’ shape. As shown in FIG. 17, the second upper drive module 314 may rotate clockwise or counterclockwise about the second direction (Y-axis direction) as an axis. In addition, the second upper drive module 314 may rotate clockwise or counterclockwise about the third direction (Z-axis direction) as an axis according to the operation of the first upper drive module 313.

The mirror mounting module 315 may be disposed into the second upper drive module 314. A space LH in which the mirror 200 is mounted may be formed in the mirror mounting module 315. The mirror mounting module 315 may fix the mirror 200 mounted in the mirror-mounted space LH. Accordingly, the mirror 200 may rotate clockwise or counterclockwise about the third direction (Z-axis direction) and the second direction (Y-axis direction) by the operation of the first upper drive module 313 and the second drive module 314.

The third upper plate 316 may be disposed on an outer side of the first upper drive module 313 so as to be opposite to the second upper drive module 314.

Referring to FIGS. 18 to 20, the lower mirror stage 320 may include a first lower plate 321, a second lower plate 322, a first lower drive module 323, a third lower plate 324, and a second lower drive module 325.

The first lower plate 321 may have a rectangular plate shape composed of sides extending in a first direction and sides extending in a second direction perpendicular to the first direction. According to one embodiment, the first direction may be an X-axis direction shown in FIGS. 19 and 20. In contrast, the second direction may be a Y-axis direction shown in FIGS. 19 and 20.

The second lower plate 322 may be disposed on the first lower plate 321 and fixedly coupled to the first lower plate 321. According to one embodiment, the second lower plate 322 may also have a rectangular plate shape like the first lower plate 321, however, the area of the second lower plate 322 may be smaller than the area of the first lower plate 321.

The first lower drive module 323 may be placed on the second lower plate 322. The first lower drive module 323 may be coupled to the second lower plate 322 to linearly reciprocate along the second direction (Y-axis direction). According to one embodiment, the first lower drive module 323 also has a rectangular plate shape like the second lower plate 322, however, the area of the first lower drive module 323 may be equal to the area of the second lower plate 322.

The third lower plate 324 may be disposed on the first lower drive module 323 and fixedly coupled to the first lower drive module 323. According to one embodiment, the third lower plate 324 may also have a rectangular plate shape like the second lower plate 322, however, the area of the third lower plate 324 may be equal to the area of the second lower plate 322.

The second lower drive module 325 may be disposed on the third lower plate 324. The second lower drive module 323 may be coupled to the third lower plate 324 to linearly reciprocate along the first direction (X-axis direction). According to one embodiment, the second lower drive module 325 may also have a rectangular plate shape like the second lower plate 322, however, the area of the second lower drive module 325 may be equal to the area of the second lower plate 322.

As a result, the mirror stage 300 includes: the upper mirror stage 310 mounted thereon with the mirror 200 for reflecting the EUV light L to change a path of the EUV light L; and the lower mirror stage 320 coupled to the upper mirror stage 310 to support the upper mirror stage 310, wherein the lower mirror stage 320 may linearly reciprocate in the first direction (X-axis direction) and the second direction (Y-axis direction), respectively, and the upper mirror stage 310 may rotate clockwise or counterclockwise about the third direction (Z-axis direction) and the second direction (Y-axis direction), respectively. Accordingly, the position of the mirror 200 coupled with the mirror stage 300 may be easily changed to have various angles. Accordingly, the incident angle of the EUV light L irradiated onto the mask M may be variously controlled.

The EUV mask inspection apparatus according to the embodiments of the present invention has been described. Hereinafter, the EUV mask inspection method according to the embodiments of the present invention will be described.

The EUV mask inspection method according to the embodiments of the present invention may include: generating first EUV light from a light source; irradiating the first EUV light onto a first region of the mask at a first angle by changing a path of the first EUV light through a mirror; collecting the first EUV light diffracted from the first region of the mask to obtain a first diffraction pattern of the diffracted first EUV light; generating second EUV light from the light source; irradiating the second EUV light onto the first region of the mask at a second angle different from the first angle by changing a path of the second EUV light through the mirror; collecting the second EUV light diffracted from the first region of the mask to obtain a second diffraction pattern of the diffracted second EUV light; implementing an illumination system by synthesizing the first diffraction pattern and the second diffraction pattern; and repeatedly calculating a target diffraction pattern synthesized from the first diffraction pattern and the second diffraction pattern by using a phase recovery algorithm, thereby obtaining an aerial image for the first region of the mask.

According to one embodiment, the irradiating of the first EUV light onto the first region of the mask at the first angle may include: changing the path of the first EUV light by changing a position of the mirror so that the first EUV light generated from the light source is irradiated to the mask; and controlling the position of a pinhole arranged in the mask to guide the first EUV light having the path changed through the mirror to be irradiated to the first region of the mask.

In addition, the irradiating of the second EUV light onto the first region of the mask at the second angle may include: changing the path of the second EUV light by changing the position of the mirror so that the second EUV light generated from the light source is irradiated to the mask; and controlling the position of the pinhole arranged in the mask to guide the second EUV light having the path changed through the mirror to be irradiated to the second region of the mask.

Accordingly, various illumination systems may be easily implemented, so that high-resolution spatial domain images can be obtained regardless of types of masks.

Although the present invention has been described in detail with reference to the preferred embodiments, the present invention is not limited to the specific embodiments and will be interpreted by the following claims. In addition, it will be apparent that a person having ordinary skill in the art may carry out various deformations and modifications for the embodiments described as above within the scope without departing from the present invention.

[Description of Reference Numerals]

| | |
|---|---|
| 100: light source | 200: Mirror |
| 300: Mirror stage | 400: Pinhole |
| M: Mask | 500: Mask stage |
| 600: Detection array | |

1. An EUV mask inspection apparatus comprising:
a light source for generating EUV light;
a mirror for changing a path of light such that the EUV light generated from the light source is emitted to a mask;
a mirror stage coupled to the mirror to control a position of the mirror such that an incident angle of the EUV light emitted to the mask is controlled; and
a detection array for collecting the EUV light diffracted through the mask to obtain a diffraction pattern of the diffracted EUV light, wherein
an illumination system is implemented by combining diffraction patterns of first EUV light and second EUV light emitted at different angles to a same region of the mask.

2. The EUV mask inspection apparatus of claim 1, wherein the detection array implements the illumination system by obtaining a target diffraction pattern by synthesizing a first diffraction pattern for the first EUV light and a second diffraction pattern for the second EUV light, and obtains an aerial image of a region of the mask irradiated with the first EUV light and the second EUV light through the target diffraction pattern.

3. The EUV mask inspection apparatus of claim 1, wherein the illumination system implemented by synthesizing the diffraction patterns for the first EUV light and the second EUV light includes a dipole illumination system having two poles spaced apart from each other at an angle of 180°.

4. The EUV mask inspection apparatus of claim 3, wherein the first EUV light is irradiated to a first region of the mask with a large angle pole (LAP) at an angle greater than 6° of an incidence angle with respect to a normal on an upper surface of the mask, and the second EUV light is irradiated to the first region of the mask with a small angle pole (SAP) at an angle smaller than 6° of the incidence angle with respect to the normal on the upper surface of the mask.

5. The EUV mask inspection apparatus of claim 1, further comprising:
a pinhole arranged on the mask, wherein
the pinhole guides the EUV light irradiated to the mask to be focused on a specific region of the mask.

6. The EUV mask inspection apparatus of claim 5, wherein the pinhole includes:
an incident hole for guiding the EUV light to be irradiated from the mirror to the mask; and
a diffraction hole for guiding the EUV light diffracted from the mask to be collected by the detection array.

7. The EUV mask inspection apparatus of claim 6, wherein the incident hole includes first to fourth incident holes, in which the second incident hole has a diameter larger than a diameter of the first incident hole, the third incident hole has a diameter larger than the diameter of the second incident hole, and the fourth incident hole has a diameter larger than the diameter of the third incident hole.

8. The EUV mask inspection apparatus of claim 1, wherein the illumination system implemented by synthesizing the diffraction patterns for the first EUV light and the second EUV light is implemented using one among:
a V-dipole illumination system having two poles spaced apart from each other at an angle of 180° in a vertical direction,
an H-dipole illumination system having two poles spaced apart from each other at an angle of 180° in a horizontal direction,
a quadrupole illumination system having four poles spaced apart from each other at an angle of 90°,
a circular illumination system having a circular pole, and
an annular illumination system having an annular pole.

9. An EUV mask inspection method comprising:
generating first EUV light from a light source;
irradiating the first EUV light onto a first region of the mask at a first angle by changing a path of the first EUV light through a mirror;
collecting the first EUV light diffracted from the first region of the mask to obtain a first diffraction pattern of the diffracted first EUV light;
generating second EUV light from the light source;
irradiating the second EUV light onto the first region of the mask at a second angle different from the first angle by changing a path of the second EUV light through the mirror;
collecting the second EUV light diffracted from the first region of the mask to obtain a second diffraction pattern of the diffracted second EUV light; and
implementing an illumination system by synthesizing the first diffraction pattern and the second diffraction pattern.

10. The EUV mask inspection method of claim 9, wherein the irradiating of the first EUV light onto the first region of the mask at the first angle includes:
changing the path of the first EUV light by changing a position of the mirror so that the first EUV light generated from the light source is irradiated to the mask; and
controlling the position of a pinhole arranged in the mask to guide the first EUV light having the path changed through the mirror to be irradiated to the first region of the mask, and wherein
the irradiating of the second EUV light onto the first region of the mask at the second angle includes:
changing the path of the second EUV light by changing the position of the mirror so that the second EUV light generated from the light source is irradiated to the mask; and
controlling the position of the pinhole arranged in the mask to guide the second EUV light having the path changed through the mirror to be irradiated to the second region of the mask.

11. The EUV mask inspection method of claim 9, further comprising:
after the implementing of the illumination system by synthesizing the first diffraction pattern and the second diffraction pattern, repeatedly calculating a target diffraction pattern synthesized from the first diffraction pattern and the second diffraction pattern by using a phase recovery algorithm, thereby obtaining an aerial image for the first region of the mask.

12. A mirror tilting apparatus comprising:
an upper mirror stage mounted thereon with a mirror for reflecting EUV light to change a path of the EUV light; and
a lower mirror stage coupled to the upper mirror stage to support the upper mirror stage, wherein
the lower mirror stage linearly reciprocates in a first direction and in a second direction perpendicular to the first direction, respectively, and
the upper mirror stage rotates clockwise or counterclockwise about a third direction perpendicular to the first and second directions and the second direction as axes.

13. The mirror tilting apparatus of claim 12, wherein the upper mirror stage includes:
a first upper drive module having an ‘L’ shape and rotating clockwise or counterclockwise about the third direction as an axis;
a second upper drive module having an ‘L’ shape and coupled into the first upper drive module to rotate clockwise or counterclockwise about the second direction as an axis; and
a mirror mounting module disposed inside the second upper drive module and having a space mounted therein with the mirror.

14. The mirror tilting apparatus of claim 12, wherein the lower mirror stage includes:
a first lower drive module linearly reciprocating along the second direction; and
a second lower drive module disposed on the first lower drive module and linearly reciprocating motion along the first direction.
